(19) United States
(12) Patent Application Publication
(10) Pub. No.: US 2023/0232576 A1
(43) Pub. Date: Jul. 20, 2023

(54) RADIATOR

(71) Applicants: CHAMP TECH OPTICAL (FOSHAN) CORPORATION, Foshan (CN); Foxconn Technology Co., Ltd., New Taipei (TW)

(72) Inventors: MENG FU, Foshan (CN); JIN-RONG XIE, Foshan (CN); WEI-DONG CHEN, Foshan (CN)

(21) Appl. No.: 17/827,903

(22) Filed: May 30, 2022

(30) Foreign Application Priority Data
Jan. 17, 2022 (CN) 202220112649.2

(51) Int. Cl. H05K 7/20

(52) U.S. Cl. CPC H05K 7/20263; H05K 7/2039; H05K 7/20772

(57) ABSTRACT

A radiator with high-temperature performance includes a radiating pipe, a heat conducting pipe, an aluminum radiating plate, a main radiating part, and an auxiliary radiating part. The radiating pipe comprises a first end in contact with a heat-generating chip, and a second end. The heat conducting pipe is arranged on both sides of the first end of the heat radiating pipe. The first end and the heat conducting pipe are nested in the aluminum radiating plate. The first heat sink is arranged on the side of the heat dissipation pipe away from the chip. The auxiliary heat dissipation part is connected with the second end. The radiator disclosed improves all-round heat dissipation efficiency and meets the heat dissipation requirements of higher chip power through the heat conduction pipe arranged on the side of the heat dissipation pipe.

### FIELD

The subject matter herein relates to technical field of heat dissipation of computer hardware, especially relates to a radiator.

### BACKGROUND

An electronic chip of a computer or server generates a lot of heat during operation. The heat generated by the chip needs to be dissipated in time, otherwise the chip may become overheat, stop running, or even burn out. At present, existing radiator in the server usually uses a heat dissipation medium to disperse heat from the chip and transfer the heat to a cooling system. As the power rates of high-performance chips can reach 300˜500 W and more, existing radiators may be difficult to meet an increased demand of heat dissipation.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a schematic view of a radiator in an embodiment according to the present disclosure.

FIG. 2 is an exploded view of the radiator of FIG. 1.

FIG. 3 is a diagram of a second heat sink of the radiator in FIG. 1.

FIG. 4 is a diagram of a radiator in another embodiment according to the present disclosure.

FIG. 5 is an exploded view of the radiator of FIG. 4.

### DESCRIPTION OF MAIN COMPONENTS OR ELEMENTS

Radiator 100;
First radiating pipe 10;
First end 11
Second end 12;
Heat conducting tube 13;
Aluminum radiating plate 20;
Copper radiating plate 30;
First heat sink 40;
First dissipation fin 41;
Depression portion 411;
Second sleeving portion 412;
Second heat sink 50;
Second dissipation fin 51;
Supporting plate 52;
Second radiating pipe 60;
Third end 61;
Fourth end 62.

### DETAILED DESCRIPTION

In order to make the above-mentioned objects, features, and advantages of the present disclosure more obvious, a description of specific embodiments of the present disclosure will be described with reference to the accompanying drawings. The present disclosure can be implemented in many ways different from those described herein, and those skilled in the art can make similar improvements without violating the contents of the present disclosure. Therefore, the present disclosure is not to be considered as limiting the scope of the embodiments to those described herein.

Several definitions that apply throughout this disclosure will now be presented.

Unless otherwise defined, all technical and scientific terms used herein have the same meaning as commonly understood by one skilled in the art. The terms used in the present disclosure herein are only for describing specific embodiments, and are not intended to limit the present disclosure.

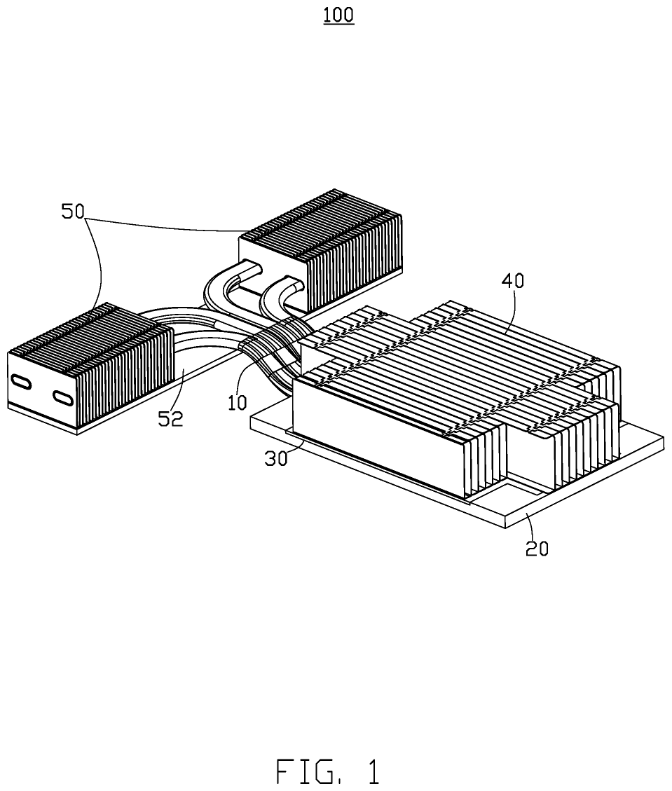

Referring to FIG. 1, a first embodiment of the present disclosure provides a radiator 100 for dissipating heat generated by a chip (not shown in figures) of a server (not shown in figures). The radiator 100 includes a plurality of first radiating pipes 10, an aluminum radiating plate 20, a plurality of heat conducting tube 13, a first heat sink 40, and a second heat sink 50. Each of the plurality of first radiating pipes 10 includes a first end 11 and a second end 12. The first end 11 is opposite to the second end 12. The first end 11 is attached to the chip. A cross section of the first end 11 is rectangular. The plurality of the heat conducting tube 13 is arranged at both sides of the first end 11 of the first radiating pipe 10. The first end 11 and the heat conducting tube 13 are embedded in the aluminum radiating plate 20, and the first end 11 and the heat conducting tube 13 are tightly attached with an inner wall of the aluminum radiating plate 20. The first heat sink 40 is arranged on a side of the heat radiating pipe 10 away from the chip. The second heat sink 50 is connected with the second end 12.

The radiator 100 of the present disclosure exports heat of the chip by contact between the first radiating pipe 10 and the chip of the server. The chip includes but is not limited to CPU, GPU, etc. A groove is defined at a middle portion of the aluminum radiating plate 20. The groove contains the first ends 11 of a plurality of heat radiating pipes 10. A side of the first end 11 of the heat radiating pipe 10 is attached to the chip, and other side of the first end 11 is attached to the first heat sink 40. The first heat sink 40 can export the heat of the chip rapidly and achieve the effect of cooling. The cross section of the first end 11 of the heat radiating pipe 10 is rectangular. When the first end 11 is embedded into the aluminum radiating plate 20, a post-processing is applied on the first end 11, the post-processing includes, but not limited to, roller processing, CNC processing, etc. Therefore, planes of the first end 11 and the aluminum heat dissipation plate 20 can be more flat, and the first end 11 can attach to the inner wall of the groove on the aluminum heat dissipation plate 20 as much as possible, which can effectively reduce gaps between the first end 11 and the aluminum radiating plate 20, maximizing the contact area between the first end 11 and the aluminum radiating plate 20, and improve the heat transfer efficiency between the first end 11 and the aluminum radiating plate 20. The first end 11 also can have better contact with a surface of the CPU to improve heat dissipation efficiency.

Since the heat conducting tubes 13 are arranged on both sides of the first end 11 of the heat radiating pipe 10, the heat conducting tube 13 can conduct the heat of the first end 11 to the aluminum radiating plate 20 from a side of the first radiating pipe 10, so as to realize all-round high-efficiency heat conduction and further improve the heat radiating efficiency.

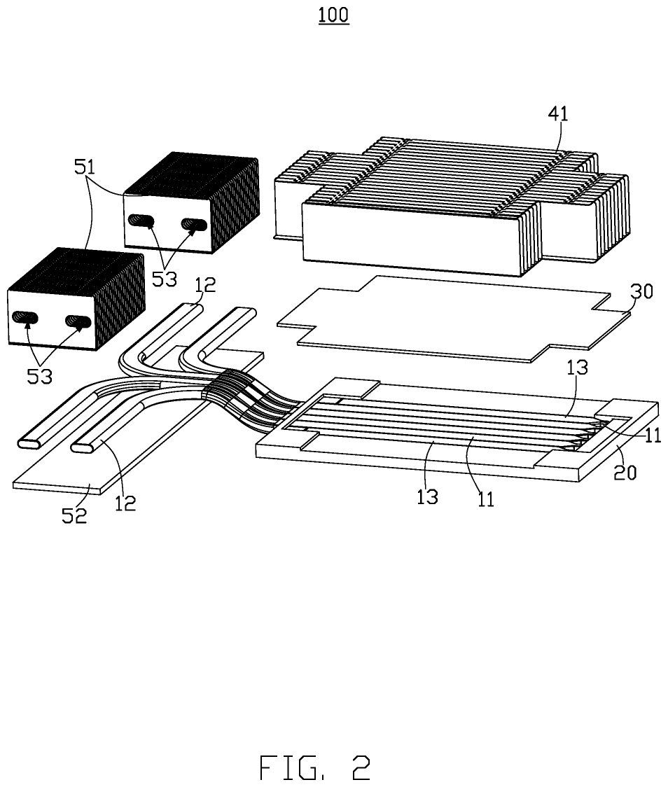

Referring to FIG. 2, the radiator 100 further includes a copper radiating plate 30. The copper radiating plate 30 is arranged between the first end 11 of the radiating pipe 10 and the first heat sink 40. The heat conduction efficiency of copper is higher than that of aluminum. Therefore, the copper radiating plate 30 can quickly disperse the heat and conduct the heat to other areas, so as to conduct the heat to the first heat sink 40 more quickly, avoiding dangerous heat accumulation near the chip when approaching a temperature range beyond what the chip can bear. The chip can be prevented from being damaged by a high temperature, and heat dissipation efficiency is improved.

In the first embodiment of the present disclosure, the first heat sink 40 includes a plurality of first dissipation fins 41. The first dissipation fins 41 are perpendicular to the aluminum radiating plate 20, and the first dissipation fins 41 are arranged parallel to the first end 11 of the heat radiating pipe 10 to facilitate heat dissipation.

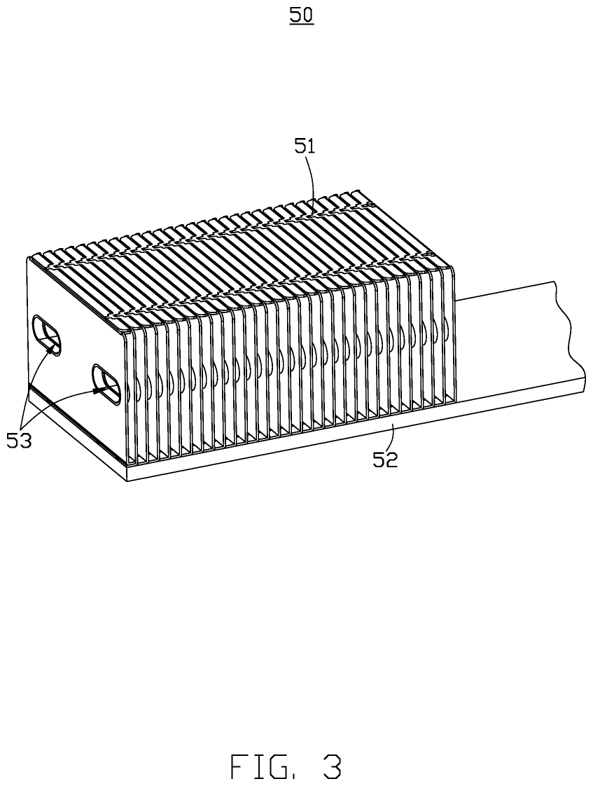

Referring to FIG. 3, in the first embodiment of the present disclosure, the second heat sink 50 includes a plurality of second dissipation fins 51 and a supporting plate 52. The second dissipation fins 51 are arranged on the supporting plate 52. The second dissipation fins 51 are perpendicular to the supporting plate 52, and are perpendicular to the second end 12 of the first radiating pipe 10.

In an embodiment of the present disclosure, an extension direction of the first end 11 is perpendicular to an extension direction of the second end 12. The second end 12 extends through the first dissipation fins 51, and the second 12 is spaced from the supporting plate 52. A connection between the first end 11 and the second end 12 is bent so that the extension direction of the first end 11 and the second end 12 is approximately perpendicular. The second end 12 penetrates through the first dissipation fin 51, so that the circumferential side of the second end 12 is in full contact with the first dissipation fin 51, increasing the rate of heat transfer, and improving the heat dissipation efficiency of the first dissipation fin 51 to the second end 12.

In the embodiment of the present disclosure, each first dissipation fin 51 defines a first sleeve portion 53, and the second end 12 is partially arranged in the first sleeve portion 53. By setting the first sleeve part 53 to accommodate the second end 12, areas for heat transferring between the second end 12 and the first dissipation fins 51 are increased, so as to improve the heat transfer effect between the second end 12 and the first dissipation fin 51, and avoid damage caused by direct contact and friction between the second end 12 and the first dissipation fin 51.

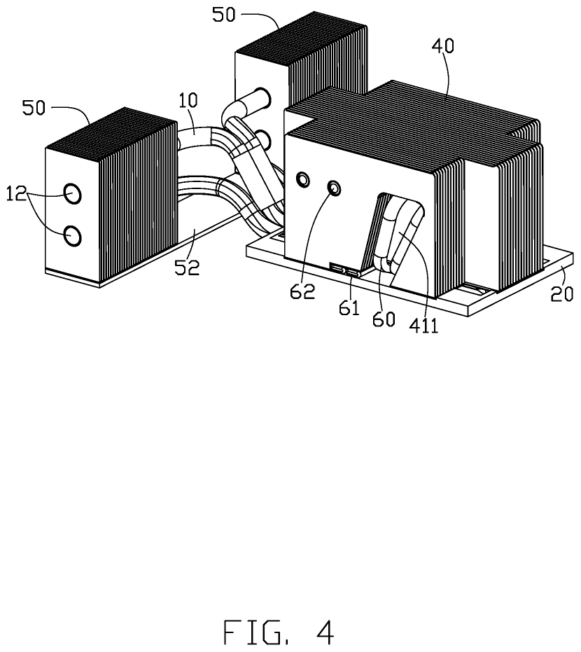

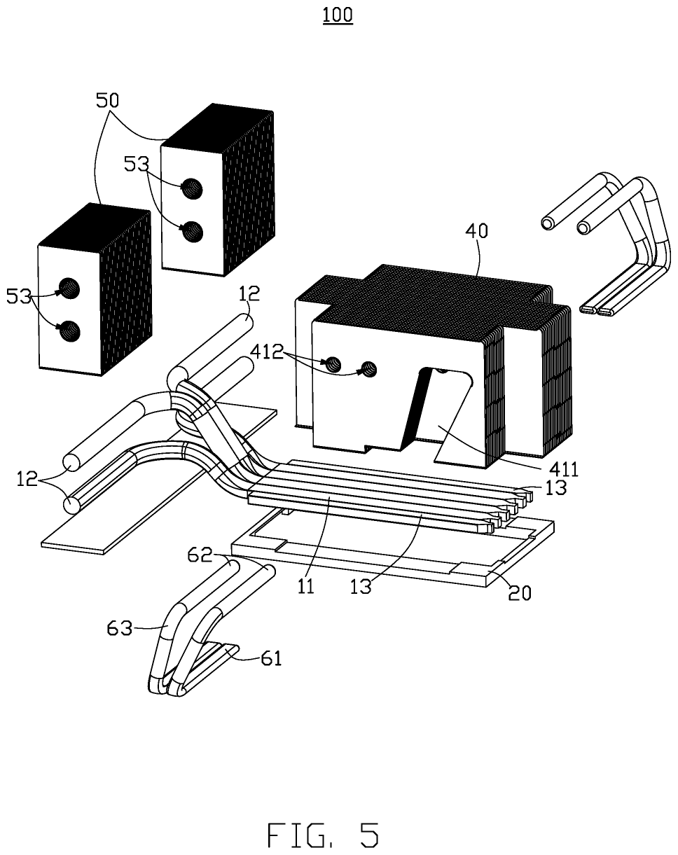

Referring to FIG. 4 and FIG. 5, a second embodiment of the present disclosure provides a radiator 100. The radiator 100 of the second embodiment is roughly the same as that of the first embodiment. The difference is that the radiator 100 of the second embodiment also includes a second radiating pipe 60. The second radiating pipe 60 includes a third end 61 and a fourth end 62. The third end 61 is embedded in the aluminum dissipation plate 20, and other parts of the second radiating pipe 60 are embedded in the first heat sink 40. The second radiating pipe 60 is in full contact with the first heat sink 40, to further strengthen the heat dissipation effect of the radiator 100.

In the second embodiment, a plurality of bent portions 63 are connected between the third end 61 and the fourth end 62 of the second radiating pipe 60. The fourth end 62 extends through the first dissipation fin 41, and the fourth end 62 is spaced from the aluminum dissipation plate 20. In the second embodiment, the third end 61 of the second radiating pipe 60 is perpendicular to the first end 11 of the first radiating pipe 10, and the fourth end 62 is roughly parallel to the third end 61. The second radiating pipe 60 roughly forms a U-shape. The fourth end 62 penetrates through the first dissipation fins 41 of the first heat sink 40 to improve the effect of heat dissipation.

In the second embodiment, the first dissipation fins 41 define a depression portion 411. The depression portion 411 is configured to accommodate the second radiating pipe 60. Specifically, connection between the third end 61 and the fourth end 62 is positioned in the depression portion 411, so that the whole second radiating tube 60 is contained in the main dissipation fin 41. The radiating effect is improved, and space occupation of the second radiating pipe 60 is reduced, accidental impacts and other damage of the second radiating pipe 60 are avoided.

In the second embodiment, the first dissipation fins 41 further include a second sleeve portion 412 for receiving the fourth end 62. Damage caused by direct contact and friction between the fourth end 62 and the first dissipation fins 41 are avoided.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A radiator configured for dissipating heat generated by a chip of a server, the radiator comprising:
a plurality of first radiating pipes, each of the plurality of first radiating pipes comprising a first end and a second end, the first end being opposite to the second end, the first end being configured to attach to the chip;
a plurality of heat conducting tubes, positioned at two opposite sides of first end of the plurality of first radiating pipes;
an aluminum radiating plate, the first end and the heat conducting tube being embedded in the aluminum radiating plate;
a first heat sink positioned at a side of the first radiating pipe away from the chip; and
a second heat sink connected to the second end.

2. The radiator of claim 1, wherein the radiator further comprises a copper radiating plate, the copper radiating plate is positioned between the first radiating pipe and the first heat sink.

3. The radiator of claim 1, wherein the first heat sink comprises a plurality of first dissipation fins, the plurality of the first dissipation fins are spaced apart from each other.

4. The radiator of claim 3, wherein the first dissipation fins are perpendicular to the aluminum radiating plate.

5. The radiator of claim 1, wherein the second heat sink comprises a plurality of second dissipation fins and a supporting plate, the plurality of the second dissipation fins are positioned on the supporting plate.

6. The radiator of claim 5, wherein the second dissipation fins are perpendicular to the supporting plate.

7. The radiator of claim 5, wherein an extension direction of the first end is perpendicular to an extension direction of the second end;
the second end extends through the second dissipation fins, and is spaced from the supporting plate.

8. The radiator of claim 7, wherein the second dissipation fins comprises a first sleeving portion, the second end is positioned in the first sleeving portion.

9. The radiator of claim 1, wherein a cross section of the first end is a rectangular.

10. The radiator of claim 9, wherein, a post-processing is applied on the first end, the post-processing comprises roller processing and/or CNC processing.

11. A radiator configured for dissipating heat generated by a chip of a server, the radiator comprising:
a plurality of first radiating pipe, each of the plurality of first radiating pipe comprising a first end and a second end, the first end being opposite to the second end, the first end being configured to attach to the chip;
a plurality of heat conducting tubes, positioned at two opposite sides of the first end of the plurality of first radiating pipe;
an aluminum radiating plate, the first end and the heat conducting tube being embedded in the aluminum radiating plate;
a first heat sink positioned at a side of the first radiating pipe away from the chip;
a second heat sink connected to the second end; and
a second radiating pipe comprising a third end and a fourth end, the second radiating pipe being embedded in the first heat sink, and the third end being attached to the aluminum radiating plate.

12. The radiator of claim 11, wherein the first heat sink comprises a plurality of first dissipation fins, the first dissipation fins are perpendicular to the aluminum radiating plate.

13. The radiator of claim 11, wherein a plurality of bent portions are connected between the third end and the fourth end, and the fourth end extends through the first dissipation fins and is spaced from the aluminum radiating plate.

14. The radiator of claim 13, wherein the first dissipating fins comprises a depression portion, the second radiation pipe is positioned in the depression portion.

15. The radiator of claim 14, wherein the first dissipating fins comprises a second sleeving portion, the fourth end is positioned in the second sleeving portion.

16. The radiator of claim 11, wherein the second heat sink comprises a plurality of second dissipation fins and a supporting plate, the plurality of the second dissipation fins are positioned on the supporting plate.

17. The radiator of claim 16, wherein the second dissipation fins are perpendicular to the supporting plate.

18. The radiator of claim 16, wherein an extension direction of the first end is perpendicular to an extension direction of the second end;
the second end extends through the second dissipation fins, and is spaced from the supporting plate.

19. The radiator of claim 18, wherein the second dissipation fins comprise a first sleeving portion, the second end is positioned in the first sleeving portion.
